(19) United States
(12) Patent Application Publication
(10) Pub. No.: US 2007/0212832 A1
(43) Pub. Date: Sep. 13, 2007

(54) Method for making a multibit transistor

(75) Inventor: Marius K. Orlowski, Austin, TX (US)

Correspondence Address: FORTKORT & HOUSTON P.C., 9442 N. CAPITAL OF TEXAS HIGHWAY, ARBORETUM PLAZA ONE, SUITE 500, AUSTIN, TX, 78759, US

(73) Assignee: Freescale Semiconductor Inc.

(21) Appl. No.: 11/370,320

(22) Filed: Mar. 8, 2006

(51) Int. Cl. H01L 21/336

(52) U.S. Cl. 438/257

(57) ABSTRACT

A method for making a transistor (301) is provided. In accordance with the method, a semiconductor substrate (201, 203) is provided, and a gate stack is formed on the substrate. The gate stack comprises first (205), second (207), and third (209) dielectric layers, wherein the second dielectric layer is disposed between said first and said third dielectric layers. A lateral recess (213) is then created in the second dielectric layer, and a charge storage material (215) is deposited in the lateral recess.

### FIELD OF THE DISCLOSURE

The present disclosure relates generally to semiconductor devices, and more particularly to methods for making memory devices.

### BACKGROUND OF THE DISCLOSURE

Conventional non-volatile memory cells typically exist in one of two states representing either a logical zero or a logical one. To increase the capacity of a memory device without significantly increasing the size of the memory, a multi-bit memory cell may be used that is capable of storing more than two states. Non-volatile memory cells of this type, referred to as multi-bit memory cells, have been historically implemented by controlling the amount of charge that is injected into portions of a charge storage layer.

FIG. 1 is an illustration of one example of a prior art two-bit EEPROM cell with asymmetric programming and reading. The device is constructed with a dielectric charge trapping layer 54 sandwiched between two silicon dioxide dielectric layers 52, 56. The charge trapping layer 54 comprises a silicon rich silicon dioxide matrix with buried polysilicon islands disposed therein. A conductive gate layer 50 is placed over the upper silicon dioxide layer 52. The memory cell is capable of storing two data bits in physically different areas of the charge trapping layer 54, namely, a right bit represented by the dashed circle 55 and a left bit represented by the dashed circle 53. A P-type substrate 62 is provided which has buried N+ source 58 and N+ drain 60 regions defined therein.

In the device depicted in FIG. 1, charges are injected independently on the source and/or drain side. Consequently, as noted above, this device provides two-bit information, since it is possible to distinguish which side of the device is bearing a charge (or if both sides are bearing a charge). However, once charge is injected into the charge trapping layer, it is essentially fixed in place. It would be more desirable for transistor performance if charge could be spread over a region instead, since this would allow better control of the threshold voltage of the transistor.

In particular, during charge injection, the gate is at medium bias. Hence, if the control gate has a potential of 5 V, the gate would be at about 2.5 V, and the drain would be at maximum bias (in this scenario, 5 V or more). This creates a high field at the drain side. The location of the field is given by the junction between the drain and the channel region. Hence, this is essentially the location of the injected charges. The injected charges must be sufficient to affect the operation of the transistor such that the level of current can be detected. Since the injected charges in the device of FIG. 1 are essentially fixed, they affect the charge flow in a limited way. However, if it was possible to spread the charge across the charge trapping layer towards the mid-channel, then the stored charge would have more of an impact on the inversion in this part of the channel and on carrier mobility, which in turn would be reflected in a lower drain current. The lower drain current would therefore be indicative of a stored charge.

FIG. 2 is an illustration of another prior art two-bit EEPROM cell. This device, like the device depicted in FIG. 1, has two polysilicon floating gates 141 and 143 with a control gate 145 disposed above them. This type of structure is advantageous over the structure of FIG. 1 in that, when a charge is injected onto one of the floating gates 141 or 143, it spreads across the entire floating gate. However, this type of structure is disadvantageous in that it requires the definition of floating gates 141 and 143 which are a fraction of the gate length of the control gate 145. Since the definition of gate lengths is a limiting feature of current technologies, the requirement of defining even smaller gate lengths renders this approach commercially unfeasible. Consequently, this approach cannot currently be used to achieve small memory cells using this approach, because the resolution of the floating gates would be the limiting factor. This approach is also disadvantageous in that it requires the floating gates to be aligned to the control gates, which represents a challenge to the overlay techniques commonly used in photolithography. As a further disadvantage of this structure, any charge leakage at the floating gate has the potential to drain the entire charge on the floating gate structure.

FIG. 3 is an illustration of yet another prior art two-bit EEPROM cell. This cell is equipped with dual floating gates 155, each of which is equipped with an independent nanocrystal charge storage region 157 that is separated from the substrate 159 by an electrically insulating layer 161, and which is separated from the gate electrode 163 by an oxide layer 165. The device is further equipped with spacer structures 167 and with source 169 and drain 171 regions.

The device of FIG. 3 is fabricated using gate replacement technology which involves forming a dummy gate, forming a passivation layer around the dummy gate, and then planarizing the passivation layer to expose the top of the dummy gate. The dummy gate is then removed by etching, thereby creating an opening in the structure. Various techniques may then be used to form the charge storage regions 157 and the gate electrode 163 within this opening.

The structure of FIG. 3 is advantageous in that, under uniform carrier injection conditions, the stored charge is spread across the floating gate structures 155, and hence affords better control over the threshold voltage of the transistor. Furthermore the structure of FIG. 3 is capable of storing two independent charge states or bits. Moreover, since the charge is isolated on islands 157 defined by the polysilicon nanocrystals, any charge leakage at the floating gate will not have the effect of draining the charge from the entire floating gate 155, as would be the case, for example, with the structure of FIG. 2. Therefore, the effect of leakage on the cell is minimized. Consequently, the time over which the cell can store charge is increased significantly. On the other hand, the structure of FIG. 3 is disadvantageous in that it requires charge to be injected uniformly over the length of the transistor. Moreover, the process used to make this type of structure requires additional passivation, planarization, masking and etching steps to form, and then remove, the dummy gate, and hence is more complex than conventional MOSFET processes.

There is thus a need in the art for a method for making a multi-bit nonvolatile memory device with multiple independent floating regions which does not rely on photolithographic techniques to form sub-resolution features, and which is comparable in complexity to a conventional MOSFET process. There is further a need in the art for such a method for making memory devices in which the charge storage regions are self-aligned to the floating gates. These and other needs may be met by the devices and methodologies described herein.

### BRIEF DESCRIPTION OF THE DRAWINGS

FIG. 1 is an illustration of a prior art two-bit EEPROM cell;

FIG. 2 is an illustration of a prior art two-bit EEPROM cell;

FIG. 3 is an illustration of a prior art two-bit EEPROM cell;

FIG. 4 is an illustration of a semiconductor device during one stage of a process in accordance with the teachings herein;

FIG. 5 is an illustration of a semiconductor device during one stage of a process in accordance with the teachings herein;

FIG. 6 is an illustration of a semiconductor device during one stage of a process in accordance with the teachings herein;

FIG. 7 is an illustration of a semiconductor device during one stage of a process in accordance with the teachings herein;

FIG. 8 is an illustration of a semiconductor device during one stage of a process in accordance with the teachings herein;

FIG. 9 is an illustration of a semiconductor device during one stage of a process in accordance with the teachings herein;

FIG. 10 is an illustration of a semiconductor device during one stage of a process in accordance with the teachings herein;

FIG. 11 is an illustration of a semiconductor device during one stage of a process in accordance with the teachings herein;

FIG. 12 is an illustration of a semiconductor device during one stage of a process in accordance with the teachings herein;

FIG. 13 is an illustration of a semiconductor device during one stage of a process in accordance with the teachings herein;

FIG. 14 is an illustration of a semiconductor device during one stage of a process in accordance with the teachings herein;

FIG. 15 is an illustration of a semiconductor device during one stage of a process in accordance with the teachings herein;

FIG. 16 is an illustration of a semiconductor device during one stage of a process in accordance with the teachings herein.

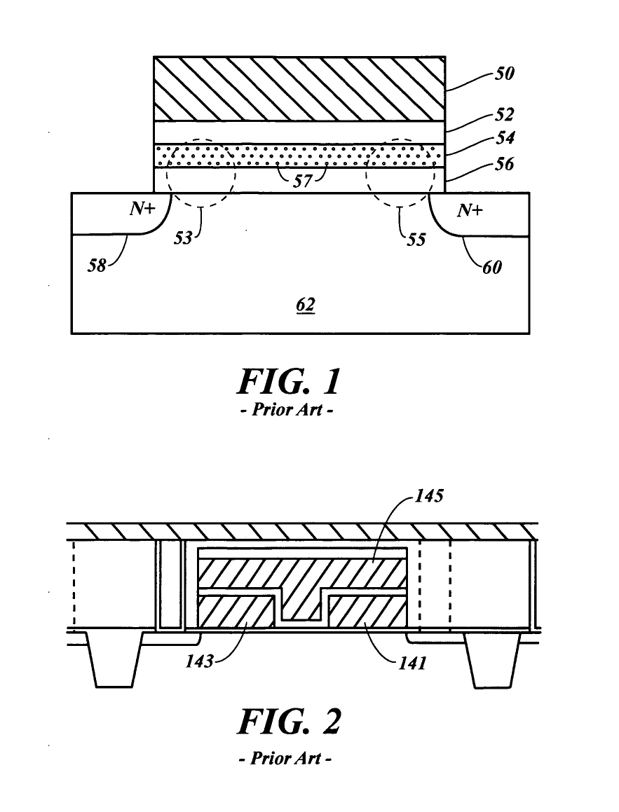

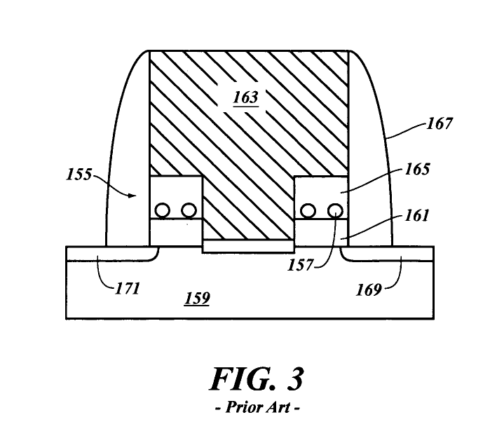

### DETAILED DESCRIPTION

In one aspect, a method for making a transistor is provided. In accordance with the method, a semiconductor substrate is provided, and a gate stack is formed on the substrate. The gate stack comprises first, second, and third dielectric layers, wherein the second dielectric layer is disposed between said first and said third dielectric layers. A lateral recess is then created in the second dielectric layer, and a charge storage material is deposited in the lateral recess.

In another aspect, a non-volatile memory device is provided herein. The memory device comprises a semiconductor substrate, and a gate stack disposed on said substrate, the gate stack comprising first, second and third dielectric layers. The second dielectric layer is recessed with respect to the first and third dielectric layers, and a charge storage material disposed in the recess in the second dielectric layer.

These and other aspects of the present disclosure are described in greater detail below.

It has now been found that the aforementioned needs may be met through the formation of a nonvolatile memory device by way of a process that utilizes a lateral recess etch to form recesses that define the location of the charge storage material in a gate stack, followed by deposition of a charge storage material in the recesses. This may be accomplished, for example, by forming a gate stack comprising three dielectric layers, of which the middle dielectric layer can be etched selectively with respect to the other two dielectric layers. The middle dielectric layer may then be etched to form at least one, and preferably two or more, lateral recesses in the stack. Subsequently, the recesses may be filled with a charge storage material, as by depositing a layer of the charge storage material over the structure and then removing the charge storage material (from all parts of the device except for the recesses) by a suitable etch back.

The methodologies described herein may permit the formation of two-bit memory cells in which the stored charge is spread over first and second distinct charge storage regions. The charge storage regions may be defined by routine etching steps, and hence do not rely on sub-resolution photolithography techniques for their definition. Moreover, the exact dimensions of these charge storage regions are not critical to the functionality of the device, and hence can vary within a relatively wide range. In addition, the structures achievable with these methods do not require the uniform injection of charge either over the entire transistor or over the charge storage regions.

As a further advantage, the methodologies provided herein may afford a simpler approach to the formation of multi-bit transistors equipped with multiple, self-aligned charge storage areas. In some embodiments, these methodologies require the definition of only a single gate, and hence avoid the need for masks, spacers or gate replacement technologies in the formation of the charge storage areas. Hence, these methodologies are comparable in complexity to conventional MOSFET processes.

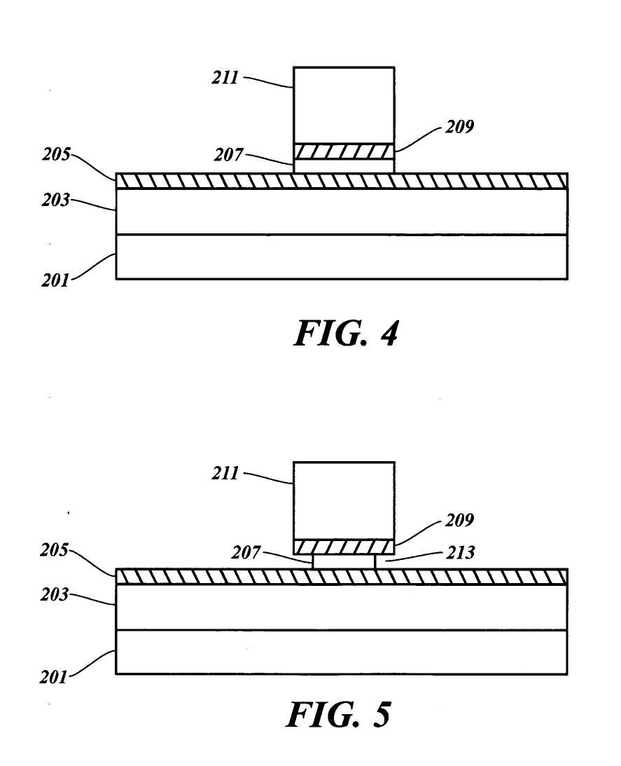

The methodologies described herein may now be understood with reference to the first particular, non-limiting embodiment depicted in FIGS. 4-7. With reference to FIG. 4, a structure is provided which comprises a substrate 201 upon which is disposed and active layer 203 and first 205, second 207 and third 209 dielectric layers. In some embodiments, layer 203 may be a bulk semiconductor substrate. The structure is equipped with a gate electrode 211 which is disposed on the third dielectric layer 209. The gate electrode 211 is aligned with the second 207 and third 209 dielectric layers. Such a structure may be achieved, for example, by depositing the materials of the second 207 and third 209 dieletric layers and the gate electrode 211 over the first dielectric layer 205, and then appropriately patterning the second 207 and third 209 dieletric layers and the gate electrode 211 through suitable masking and etching techniques.

Preferably, the second dieletric layer 207 comprises a material that may be etched selectively with respect to the first 205 and third 209 dieletric layers. This may be achieved for example, by using silicon nitride as the second dielectric layer 207 and silicon oxide as the first 205 and third 209 dielectric layers, although various other material choices are also possible. In such a construction, the silicon nitride may be selectively etched using, for example, various fluorine-containing plasmas, such as those generated from NF₃, CₓF_{y}, CₓF_{y}H, and like materials, or hot phosphoric acid. Moreover, while it is desirable in some embodiments for the first 205 and third 209 dielectric layers to have the same composition, this is not necessary, so long as the aforementioned etch selectivity is attained. The use of metal oxides in one or more of the first 205, second 207 and third 209 dielectric layers may also be desirable in some applications.

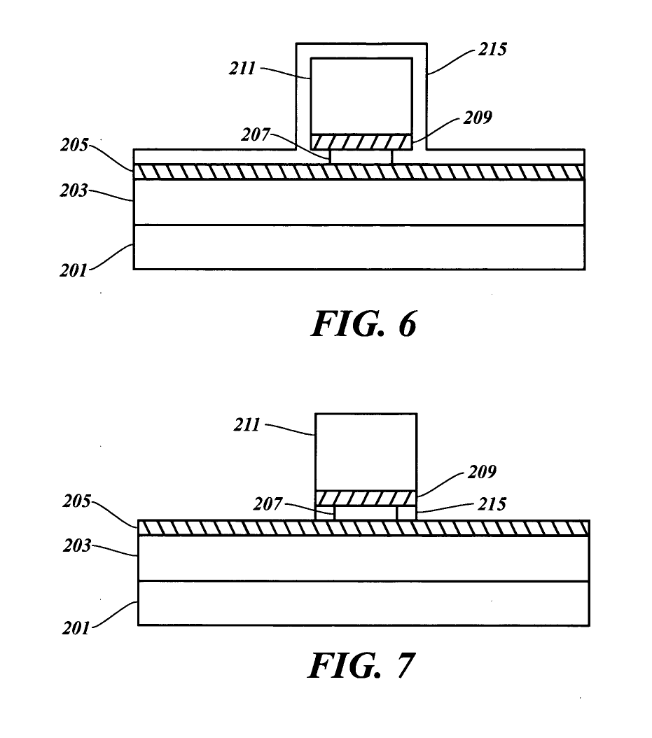

As seen in FIG. 5, the second dielectric layer 207 is then selectively etched (under-etched) with respect to the first 205 and third 209 dielectric layers to create first and second lateral recesses 213 therein. The extent of the under-etch is not particularly critical in most applications. Typically, some minimal amount of under-etching must be achieved to provide a large enough recessy for a sufficient amount of charge storage material to be deposited therein (see FIG. 6 and the associated text), and the dimensions of this recess will be determined by the particular application and transistor requirements to which the fabrication process is directed. For example, in a 90 nm technology node that utilizes gate widths of about 60 nm, a minimum under-etch of 10-20 nm might be suitable. In some applications, the under-etching may also be subject to some maximum amount dictated by the need to maintain a dielectric barrier between the subsequently deposited charge storage areas. In some embodiments, as when the charge storage material utilized is a nanocrystal charge storage material (such as a material comprising nanocrystals of polysilicon disposed in a silicon nitride matrix), there may be no maximum amount of under-etching, since it is possible to isolate charges in multiple locations on a single layer of such material.

As shown in FIG. 6, a (preferably conformal) layer of a suitable charge storage material 215 is then deposited over the structure. Some particular, non-limiting examples of suitable charge storage materials include SiGe, Si (both amorphous and polycrystalline), Ge, and nanocrystal charge storage materials. In many applications, the use of a SiGe alloy with a germanium content of about 25% is preferred as a charge storage material, since such an alloy can be selectively etched with respect to silicon at a very high selectivity ratio. The charge storage material 215 may be doped or undoped. The use of a conformal film of charge storage material 215 in conjunction with sufficiently low deposition rates is found to be suitable for filling the first and second lateral recesses 213 with the charge storage material 215.

As shown in FIG. 7, the layer of charge storage material 215 is then etched back with a suitable etchant, thereby leaving a portion of the charge storage material 215 disposed in the lateral recesses 213. This may be achieved, for example, by utilizing an etch that is either anisotropic, or mainly anisotropic but which has a small isotropic component. In some embodiments, this etch may also be utilized to reduce the width of any spacer structures that are present at the time of the etch, although it is also possible to use an etch that is also selective to the materials of the spacer structures (or, put another way, to use spacer structure materials that are resistant to this etch).

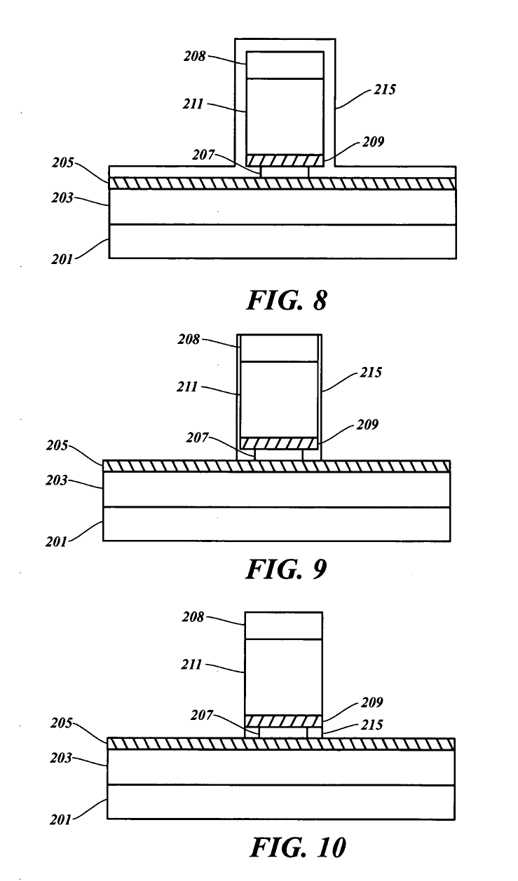

FIGS. 8-10 illustrate one possible variation of the process depicted in FIGS. 4-7. In FIG. 8, a conformal layer of charge storage material 215 is deposited over the structure as in the previously described embodiment. However, as shown in FIG. 9, in this variation, the charge storage material 215 is not completely removed from the sidewalls of the gate electrode 211, due to the anisotropy of the etch. Subsequently, as shown in FIG. 10, the structure is subjected to a (preferably timed) oxidation step to remove the residual portion of the charge storage material 215 disposed on the side walls of the gate electrode 211, without converting it to an oxide in the lateral cavities.

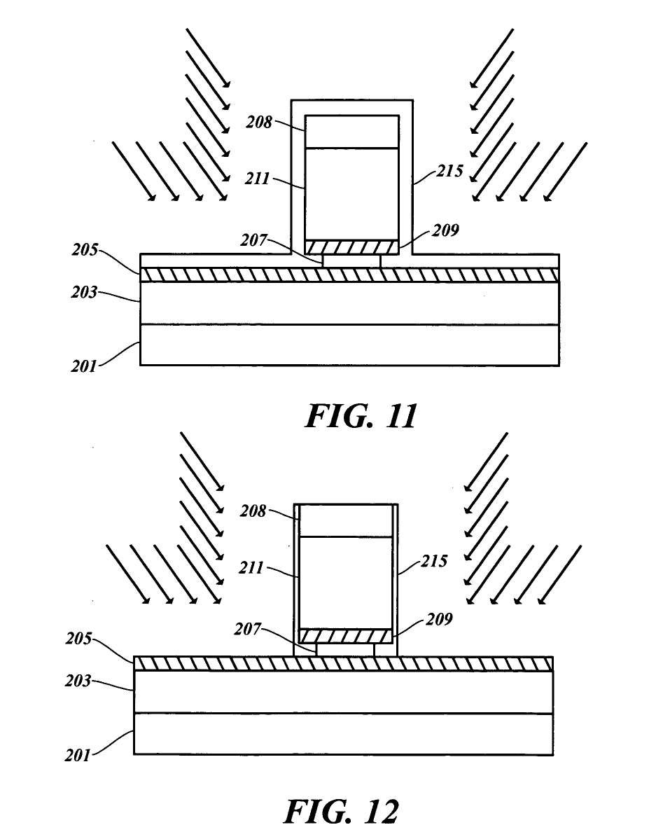

FIGS. 11-12 illustrate another particular, non-limiting embodiment of the methodology disclosed herein. In FIG. 11, a conformal layer of charge storage material 215 is deposited over the structure as in the previously described embodiment. The conformal layer of charge storage material 215 is then treated to change its etch characteristics with respect to the untreated material. For example, the conformal layer of charge storage material may be subjected to a low energy, medium dose implant of various species, including, for example, species such as Ge or Xe, which changes the crystallinity of the charge storage material, as by rendering it more amorphous. Thus, for example, if the charge storage material is a polycrystalline material such as SiGe, treatment with species such as Ge or Xe can be utilized to render the material more amorphous. Since amorphous SiGe etches much faster than polycrystalline SiGe, and since the portion of the charge storage material which is disposed in the recesses will be largely shielded from this treatment (this may be further ensured through control of the depth and/or angle of the implant), such a treatment, followed by a suitable etch, can be utilized to realize a structure in which a portion of the charge storage material is disposed in the lateral recesses. While FIG. 11 depicts the application of this treatment to the conformal layer of charge storage material 215, as shown in FIG. 12, this treatment can also be applied after the bulk of the charge storage material 215 has been removed by a suitable etch.

A number of variations are possible to the embodiment depicted in FIGS. 11-12. For example, materials such as BF₂, P, As and Sb may be used to doped the charge storage material, either after the charge storage material has been deposited as a conformal layer, or after a portion of the conformal layer has been removed by etching. Thus, for example, in the case of SiGe, doped SiGe (at medium to high doping levels of 5×10¹⁸-5×10²⁰) etches faster than undoped SiGe. Similarly, doping with F, Br or Cl can be used to similar advantage, since the presence of these materials in the conformal layer of charge storage material promotes faster etching of the top portion of the conformal layer.

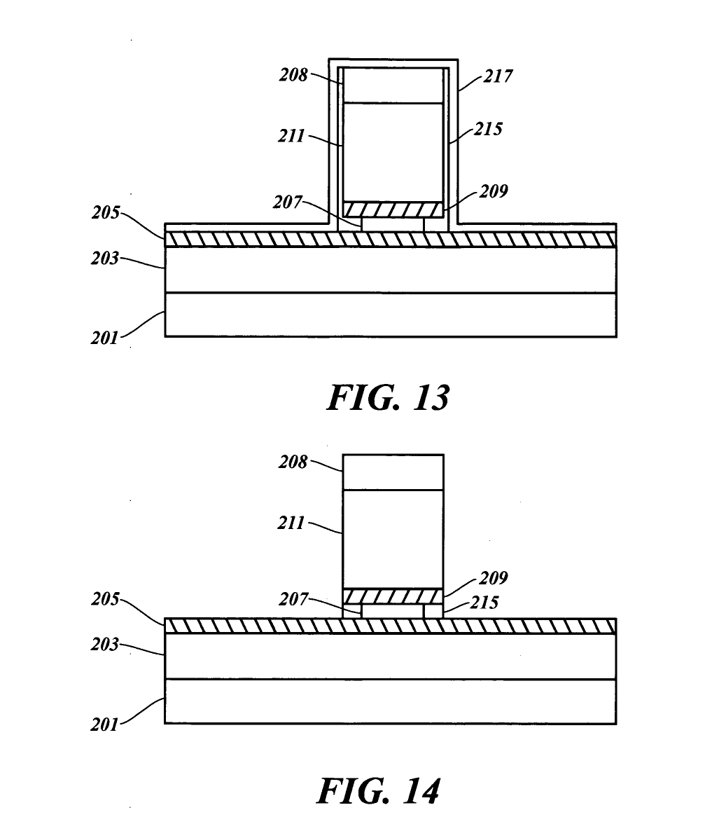

FIGS. 13-14 illustrate a further particular, non-limiting embodiment of the methodology disclosed herein. The structure of FIG. 13 is essentially identical to the structure of FIG. 9, except that a metal layer 217 has been deposited over the structure. Preferably, the metal layer 217 is deposited to a thickness of about 20 to 50 Å. The metal layer 217, which may be a metal such as nickel, is then subjected to a silicide reaction at a temperature of less than 500° C., and the excess metal is removed. Next, as shown in FIG. 14, the layer of silicide is removed with a suitable etchant such as HF. Such an etch is capable of removing silicide with an extremely high selectivity to the polysilicon of the gate electrode 211. A subsequent etch using a mixture of NH₄OH, H₂O₂ and deionized water (sometimes referred to in the industry as an SCi etch or clean) can be used to clean exposed portions of the gate dielectric material and remaining gate conductor material. One advantage of this approach is that removal of the silicide can be made to remove any residual charge storage material from the sidewalls of the gate. Removal of the silicide can also be used to uniformly remove a portion of the gate. Hence, this approach can be utilized to produce a gate electrode of reduced thickness.

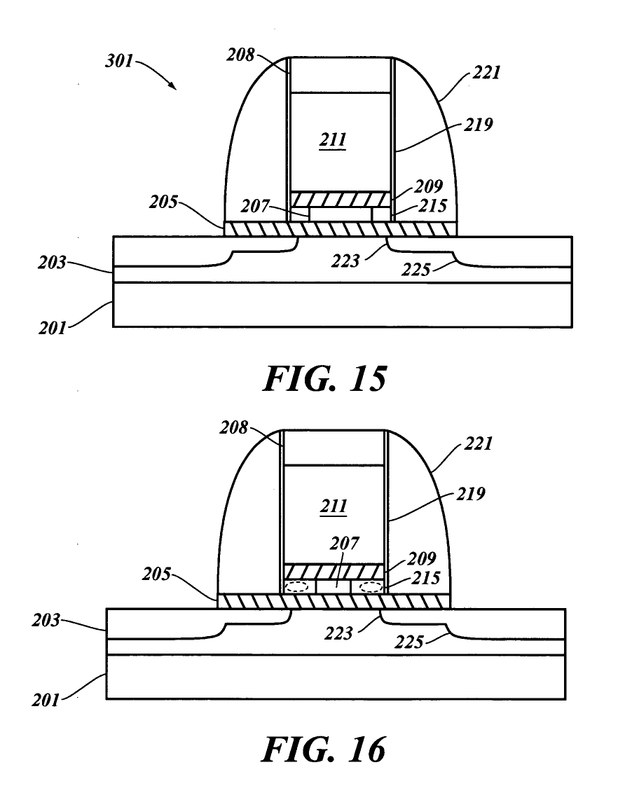

FIG. 15 depicts a completed two-bit floating gate transistor 301 made in accordance with the teachings herein. As seen therein, a pair of dielectric spacers 221 has been formed on the sidewalls of the gate electrode 211 by conventional deposition and etch techniques. Also, source/drain extension regions 223 and deep 225 source/drain implant regions have been formed in the active layer 203.

FIG. 16 illustrates the transistor of FIG. 15 after charge injection has occurred. In the transistor depicted therein, the charge storage areas are self-aligned to the gate electrode, which is a natural consequence of some of the fabrication methodologies described herein. A number of the advantages attainable with the methodologies described herein can be appreciated with respect to FIG. 16. For example, as is readily apparent from the figure, since the stored charges are confined to the narrow regions at the source/drain junctions, the extent of the recess etch is not particular critical, so long as a portion of the second dielectric layer 207 remains intact.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A method for making a non-volatile memory device, comprising:
forming a gate stack, the gate stack comprising first, second, and third dielectric layers, wherein said second dielectric layer is disposed between said first and said third dielectric layers;
creating a lateral recess in said second dielectric layer; and
forming a charge storage structure, wherein the step of forming a charge storage structure includes the step of depositing a charge storage material in said lateral recess.

2. The method of claim 1, wherein the step of creating a lateral recess in said second dielectric layer comprises creating first and second lateral recesses in said second dielectric layer.

3. The method of claimed 2, wherein the step of depositing a charge storage material in said lateral recess comprises depositing a charge storage material in said first and second lateral recesses.

4. The method of claim 1, wherein said gate stack comprises a gate electrode that is disposed over said third dielectric layer.

5. The method of claim 1, wherein said charge storage material is selected from the group consisting of Si, Ge and SiGe.

6. The method of claim 1, wherein said lateral recess is created through the use of an etch that selectively etches the material of the second dielectric layer with respect to the first and third dielectric layers.

7. The method of claim 1, wherein the charge storage material is deposited in the lateral recess by depositing a conformal layer of charge storage material over the gate stack.

8. The method of claim 7, wherein the conformal layer of charge storage material is etched after it is deposited over the gate stack.

9. The method of claim 8, wherein said etch leaves a portion of the conformal layer of charge storage material on the sides of the gate electrode.

10. The method of claim 9, wherein the portion of charge storage material remaining on the sides of the gate electrode is removed by gate oxidation.

11. The method of claim 9, wherein the portion of charge storage material remaining on the sides of the gate electrode is removed by siliciding the gate electrode, followed by removal of the silicide.

12. The method of claim 11, wherein the silicide is removed by exposure of the gate stack to HF, followed by treatment of the gate stack with an aqueous solution of NH₄OH and H₂O₂.

13. The method of claim 9, wherein the portion of charge storage material remaining on the sides of the gate electrode is removed by implanting it with an implant material that changes the crystallinity of the charge storage material.

14. The method of claim 13, wherein the implant material renders the charge storage material more amorphous.

15. The method of claim 14, wherein the implant material is selected from the group consisting of Ge and Xe.

16. The method of claim 14, wherein the charge storage material is subsequently etched, and wherein the charge storage material etches at a faster rate when it is an amorphous state than when it is in a more crystalline state.

17. The method of claim 9, wherein the portion of charge storage material remaining on the sides of the gate electrode is removed by doping the conformal layer of charge storage material with a dopant that changes the etch rate of the charge storage material.

18. The method of claim 17, wherein the dopant is selected from the group consisting of F, BF₂, P, As and Sb.

19. The method of claim 1, wherein said transistor is a non-volatile memory device.

20. A non-volatile memory device, comprising:
a semiconductor substrate;
a gate stack disposed on said substrate, said gate stack comprising first, second and third dielectric layers, and wherein said second dielectric layer is recessed with respect to said first and said third dielectric layers; and
a charge storage material disposed in said recess in said second dielectric layer.
